(19) United States
(12) Patent Application Publication
(10) Pub. No.: US 2026/0360658 A1
(43) Pub. Date: Nov. 12, 2026

(54) ABERRATION CORRECTOR, CHARGED PARTICLE BEAM DEVICE, AND ABERRATION CORRECTION METHOD

(71) Applicant: Hitachi High-Tech Corporation, Tokyo (JP)

(72) Inventors: Mihiro TAKASAKI, Tokyo (JP); Hirokazu TAMAKI, Tokyo (JP)

(73) Assignee: Hitachi High-Tech Corporation, Tokyo (JP)

(21) Appl. No.: 19/142,268

(22) PCT Filed: Jan. 18, 2023
(86) PCT No.: PCT/JP2023/001306

§ 371 Date: Jun. 23, 2025

(51) Int. Cl. H01J 37/153; H01J 37/141; H01J 37/28

(52) U.S. Cl. CPC H01J 37/153; H01J 37/141; H01J 37/28; H01J 2237/1534; H01J 2237/2802

(57) ABSTRACT

An aberration corrector comprises: first and second multipoles placed along an optical axis and capable of exciting a 6-pole field; first and second electromagnetic lenses placed between the first and second multipoles and constituting a transfer optical system; and a third multipole placed at a crossover of the transfer optical system and capable of exciting a 4-pole field, at least one of the strength and rotation angle of the 4-pole field excited by the third multipole being controlled to selectively control four-fold symmetric third-order astigmatism.

### TECHNICAL FIELD

The present invention relates to an aberration corrector, a charged particle beam device, and an aberration correction method.

### BACKGROUND ART

Certain charged particle beam devices such as a transmission electron microscope (TEM) and a scanning transmission electron microscope (STEM) are provided with an aberration corrector for correcting a spherical aberration of an objective lens. As such an aberration corrector, one using a multipole that generates a multipole field is known. The aberration corrector corrects a spherical aberration of the objective lens and generates a parasitic aberration due to its imperfection. Therefore, in order to sufficiently exhibit performance of the aberration corrector, it is necessary to perform control for correcting the parasitic aberration.

PTL 1 discloses a structure of an aberration corrector that corrects third-order and lower parasitic aberrations. In order to correct four-fold symmetric third-order astigmatism (hereinafter, referred to as “A3”), which is one type of parasitic aberration, a method is disclosed in which a deflector is used to tilt a trajectory of an electron beam incident on two multipoles of an aberration corrector in a coordinated manner.

In order to implement higher resolution of the charged particle beam device, studies are underway to correct a higher-order parasitic aberration. PTL 2 discloses a multipole corrector for correcting a sixth-order aberration and/or higher-order aberration.

### CITATION LIST

### Patent Literature

PTL 1: JP2012-234755A
PTL 2: JP2021-82593A

### SUMMARY OF INVENTION

### Technical Problem

In control of a parasitic aberration of an aberration corrector, an aberration amount for each parasitic aberration is measured, aberration correction is performed preferentially from a parasitic aberration having a large aberration amount, and measurement of the aberration amount and the aberration correction are repeated until all the parasitic aberrations to be controlled finally converge to an allowable value or less. Since the aberration correction changes the trajectory of the electron beam in the aberration corrector, by reducing the aberration amount of one parasitic aberration, the aberration amount of another parasitic aberration may be increased. When a degree of increasing another parasitic aberration is large, the aberration correction for reducing the aberration amount of the increased another parasitic aberration is further required, and thus a time required for setting a parameter for controlling the parasitic aberration of the aberration corrector increases. Therefore, it is desirable that the method for controlling the parasitic aberration is a control method that does not vary another parasitic aberration as much as possible.

In the method disclosed in PTL 1, since the trajectory of the electron beam is tilted on a hexapole field, a change in a parameter for controlling A3 (in this case, a tilt angle of the trajectory of the electron beam) has a large influence on other parasitic aberrations. It is desirable to selectively control A3 without using a deflector.

PTL 2 discloses a sixth-order correction STEM multipole corrector system including an intermediate multipole and a pair of transfer lenses, and it can be read that the intermediate multipole is disposed at a crossover. However, the control of A3 is not disclosed.

### Solution to Problem

An aberration corrector according to an embodiment of the invention includes: first and second multipoles disposed along an optical axis and configured to excite a hexapole field; first and second electromagnetic lenses disposed between the first multipole and the second multipole and constituting a transfer optical system; and a third multipole disposed at a crossover of the transfer optical system and configured to excite a quadrupole field. At least one of a strength and a rotation angle of the quadrupole field excited by the third multipole is controlled to selectively control a four-fold symmetric third-order astigmatism.

### Advantageous Effects of Invention

In the aberration corrector, it is possible to correct the four-fold symmetric third-order astigmatism while preventing the influence on other parasitic aberrations. Other technical problems and novel features will become apparent from description of the present description and the accompanying drawings.

### BRIEF DESCRIPTION OF DRAWINGS

FIG. 1 is an example of an overall configuration of a scanning transmission electron microscope.

FIG. 2 is an example of an optical system of an aberration corrector.

FIG. 3A is a cross-sectional view (schematic view) of a hexapole in a plane perpendicular to an optical axis.

FIG. 3B is a cross-sectional view (schematic view) of a quadrupole in a plane perpendicular to the optical axis.

FIG. 4A is another example of the optical system of the aberration corrector.

FIG. 4B is another example of the optical system of the aberration corrector.

FIG. 4C is another example of the optical system of the aberration corrector.

FIG. 5 is a cross-sectional view (schematic view) of an octupole in a plane perpendicular to the optical axis.

FIG. 6A is a flow showing a calculation process of an A3 correction coefficient Cm and an A3 correction angle coefficient Ca.

FIG. 6B is a flow showing a process for setting a parameter for controlling A3 to be equal to or less than an allowable amount.

FIG. 6C is a diagram for illustrating a method for setting a control amount of a quadrupole field.

FIG. 7 is an example of a GUI.

FIG. 8 is a diagram for illustrating an effect of the present embodiment.

FIG. 9 is a diagram for illustrating an effect of the present embodiment.

### DESCRIPTION OF EMBODIMENTS

Hereinafter, a preferred embodiment of the invention will be described with reference to the drawings.

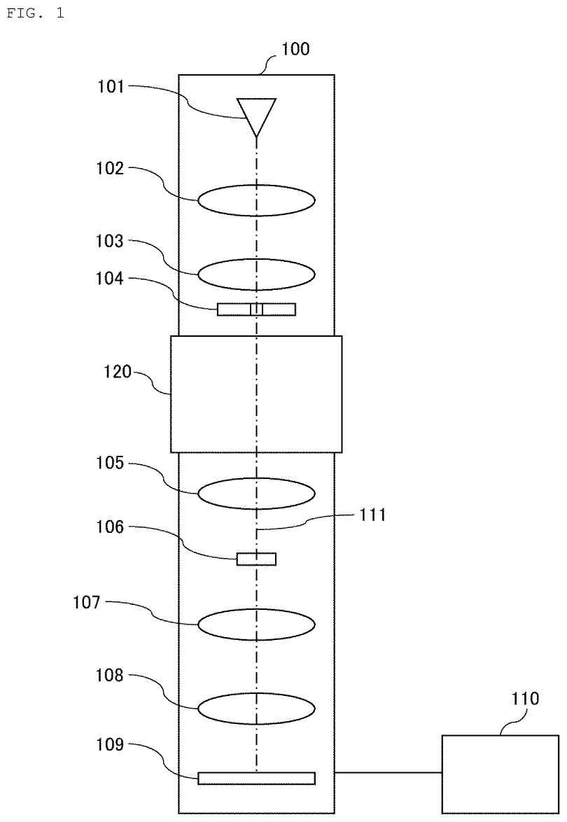

FIG. 1 is an example of an overall configuration of a scanning transmission electron microscope (STEM) which is one of charged particle beam devices. The STEM is a device that generates a transmission electron image by irradiating a sample with an electron beam and detecting transmission electrons transmitted through the sample, and includes a mirror body 100 and a controller 110.

The controller 110 controls each unit included in the mirror body 100 and generates an observation image based on a detection signal transmitted from the mirror body 100. The controller 110 includes, for example, a computer.

The mirror body 100 accommodates, as main components, an electron optical system including an electron source 101, focusing lenses 102, 103, an aperture 104, an aberration corrector 120, a pre-objective lens 105, a post-objective lens 107, and a projection lens 108, and a detector 109 constituting a detection system. Axes of the focusing lenses 102, 103, the aperture 104, the aberration corrector 120, the pre-objective lens 105, the post-objective lens 107, the projection lens 108, and the detector 109 are aligned with an optical axis 111.

The electron source 101 emits an electron beam to irradiate the sample 106. The emitted electron beam is accelerated by a predetermined acceleration voltage, and then focused by the focusing lenses 102, 103 to pass through the aperture 104. The electron beam passed through the aperture 104 is corrected for aberration such as a spherical aberration by the aberration corrector 120, and then focused onto a surface of a sample 106 by the pre-objective lens 105. The electron beam transmitted through the sample 106 is focused by the post-objective lens 107 and then projected onto the detector 109 by the projection lens 108. The detector 109 detects the projected electron beam and transmits a detection signal to the controller 110.

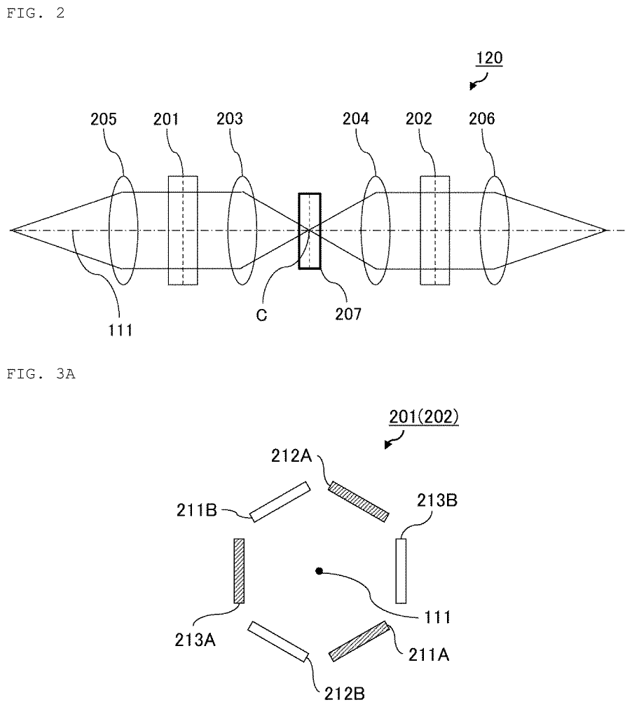

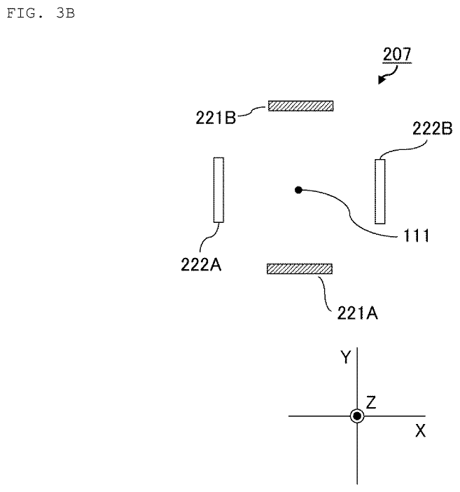

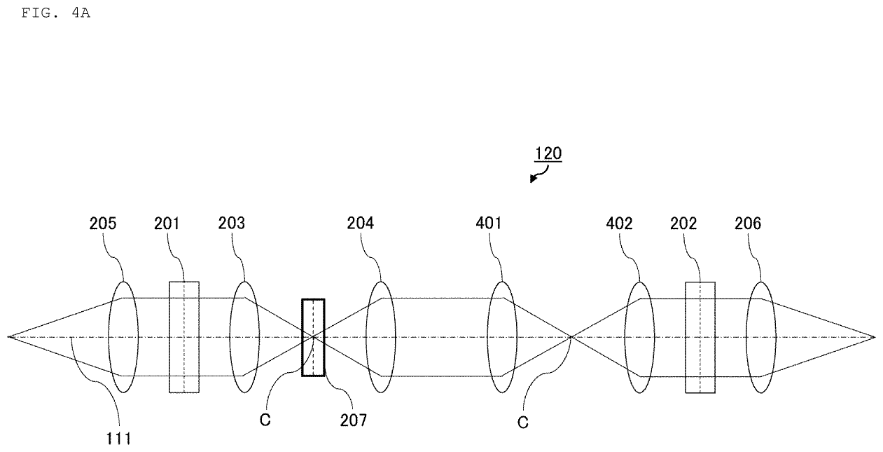

FIG. 2 shows an example of an optical system of the aberration corrector 120 according to the present embodiment. The aberration corrector 120 shown in FIG. 2 is an aberration corrector using a hexapole field, and includes, as a basic configuration, a first multipole 201, a second multipole 202, a first electromagnetic lens 203, and a second electromagnetic lens 204. The first multipole 201 and the second multipole 202 are multipoles capable of exciting the hexapole field. FIG. 3A is a cross-sectional view (schematic view) of a hexapole in a plane perpendicular to the optical axis 111. Here, in order to simplify the description, the multipole 201 (202) will be described as a hexapole having six poles. As shown in FIG. 3A, opposing pole pairs (211A, B), (212A, B), and (213A, B) in the hexapole are excited to form opposite pole pairs. For example, the hexapole field is excited by exciting the poles 211A, 212A, and 213A to an N pole and exciting the poles 211B, 212B, and 213B to an S pole. The electron beam passing through a hexapole field is distorted into a triangular shape by its action (a secondary aberration), and a negative spherical aberration occurs.

The first electromagnetic lens 203 and the second electromagnetic lens 204 constitute a transfer optical system having a magnification of 1, and have a function of inverting electron trajectories incident on the two multipoles 201, 202. Accordingly, the electron beam passing through the first multipole 201 is inverted while maintaining a shape distorted into the triangular shape and is incident on the second multipole 202. As a result, the secondary aberration generated in a first multipole 201 is canceled and the triangular-shaped distortion of the electron beam is eliminated, while the negative spherical aberration remains. The negative spherical aberration can cancel a positive spherical aberration generated by the objective lens.

In the present embodiment, a third multipole 207 for generating a quadrupole field at a crossover C of the transfer optical system is provided. The inventors find that A3 can be controlled by controlling the quadrupole field excited in the third multipole 207. In this case, since it is not necessary to tilt the trajectory of the electron beam in order to control A3, the influence of the control of A3 on other parasitic aberrations can be reduced. FIG. 3B is a cross-sectional view (schematic view) of the quadrupole in a plane perpendicular to the optical axis 111. Here, in order to simplify the description, the multipole 207 will be described as the quadrupole having four poles. As shown in FIG. 3B, the opposing pole pairs (221A, B) and (222A, B) in the quadrupole are excited to be the same pole pair. For example, the quadrupole field is excited by exciting the poles 221A and 221B to the N pole and exciting the poles 222A and 222B to the S pole. Here, when a direction of the optical axis 111 is a Z direction and a plane perpendicular to the optical axis 111 is an XY plane, the quadrupole functions as, for example, an asymmetric lens in which an XZ plane has a concave lens action and a YZ plane has a convex lens action. Therefore, by generating the quadrupole field at an appropriate rotation angle in the crossover C, it is possible to bring A3 close to 0.

In FIG. 2, a third electromagnetic lens 205 and a fourth electromagnetic lens 206 serve to adjust an electron beam incident on the optical system of the aberration corrector 120 from the electron optical system and an electron beam emitted from the optical system of the aberration corrector 120 to the electron optical system, respectively. Here, the third electromagnetic lens 205 converts the electron beam into a collimated beam, and the fourth electromagnetic lens 206 refocuses the collimated beam.

Here, the multipole is a general term for a lens having a structure in which an even number of poles (magnetic poles in the present embodiment) are arranged on the plane perpendicular to the optical axis. Although FIG. 3A shows an example of the hexapole and FIG. 3B shows an example of the quadrupole, the first multipole 201 and the second multipole 202 are not limited to the hexapole as long as at least the hexapole field can be excited so that, for example, a dipole field, a quadrupole field, a hexapole field, an octupole field, and a dodecapole field can be excited by a dodecapole. Similarly, the third multipole 207 is not limited to a quadrupole as long as it can excite at least a quadrupole field. The multipole can excite a plurality of pole fields in a superimposed manner. In order to control the parasitic aberration, in addition to the above-described pole field, another pole field may be superimposed and excited in the multipoles 201, 202, and 207.

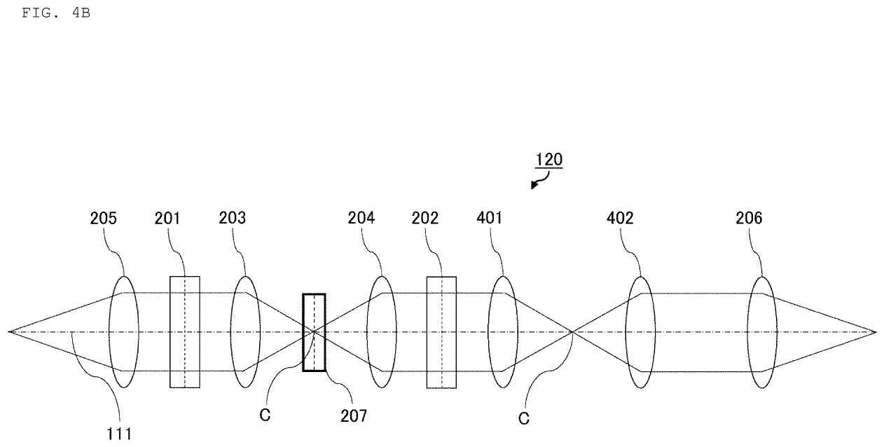

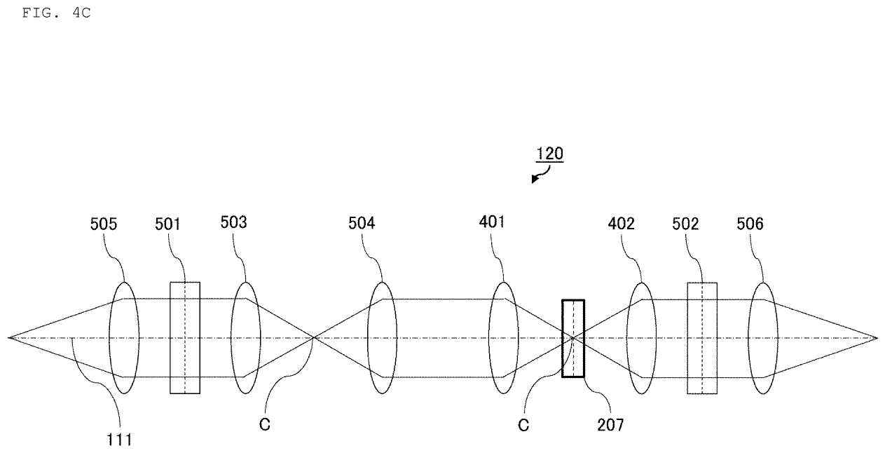

Although FIG. 2 shows an example of an optical system having the simplest configuration of the aberration corrector 120, an optical element may be added in order to increase parameters for selectively controlling various parasitic aberrations. FIGS. 4A to 4C show an example of an optical system in which a fifth electromagnetic lens 401 and a sixth electromagnetic lens 402 constituting a transfer optical system having a magnification of 1 are added to the optical system shown in FIG. 2. These optical systems have two crossovers C in the entire optical system of the aberration corrector 120. Also in such an example, A3 can be controlled as long as the third multipole 207 capable of exciting the quadrupole field is disposed at the crossover located between the first multipole 201 and the second multipole 202 capable of exciting the hexapole field. In the optical systems of FIGS. 4A and 4C, two crossovers are present between the first multipole 201 and the second multipole 202. Therefore, the hexapole field excited by the second multipole 202 in the optical system of FIG. 2 or FIG. 4B is a hexapole field in the same rotation direction as the hexapole field excited by the first multipole 201, whereas the hexapole field excited by the second multipole 202 in the optical system of FIGS. 4A and 4C is a hexapole field rotated by 180° with respect to the hexapole field excited by the first multipole 201. Accordingly, in either case, the distortion of the electron beam can be eliminated, and the negative spherical aberration for canceling the positive spherical aberration of the objective lens can be generated.

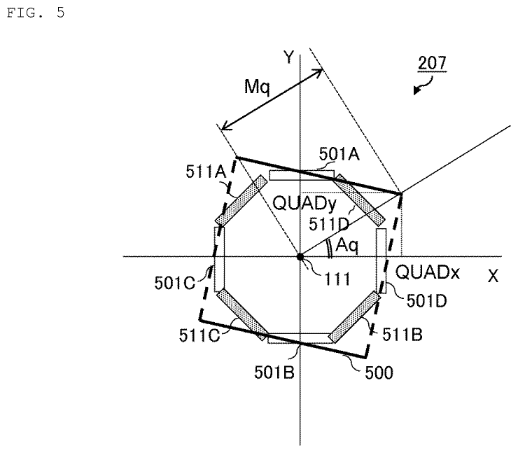

Next, a control method of A3 will be described. FIG. 5 shows an example in which an octupole that can be used as two sets of quadrupoles is used as the third multipole 207, and shows a cross-sectional view (schematic view) in a plane perpendicular to the optical axis 111. The octupole can be regarded as a combination of a quadrupole configured with poles 501A to 501D and a quadrupole configured with poles 511A to 511D, and in the case of the octupole, by controlling a magnetic field excited in each of the poles 501A to 501D and 511A to 511D, a strength Mq and a rotation angle Aq of the quadrupole field 500 excited by the third multipole 207 (here, schematically shown as a square configured with a broken line and a solid line) can be freely controlled. The quadrupole field 500 is represented by (Mq, Aq) or (Mq,Pq) using Mq and Aq (or Pq described later), and can also be represented by (QUADx,QUADy) as a two-dimensional coordinate system.

Since the quadrupole field is a two-fold symmetric field, a quadrupole field at a certain rotation angle Aqs is the same as a quadrupole field at a rotation angle (Aqs+180 degrees). Therefore, the rotation angle of the quadrupole field in all directions can be expressed by a range of 180 degrees such as “0 degrees to 180 degrees” or “−90 degrees to 90 degrees”. In addition, since one period is achieved by rotating 180 degrees spatially, it is also possible to use twice the spatial rotation angle (Pq=2×Aq) instead of Aq and express it as 0 degrees to 360 degrees or −180 degrees to 180 degrees. Here, among four vertices of the square imitating the quadrupole field, attention is paid to a vertex that is sandwiched between a solid line and a dashed line in a clockwise direction and that is present in either a first quadrant, a second quadrant, on an X-axis where X>0, or on a Y-axis where Y>0, the rotation angle of the quadrupole field is defined by a direction from the center of the quadrupole field to the corresponding vertex, and an orientation of the quadrupole field having a vertex on the X-axis where X>0 is set to Aq=0. However, the orientation of the quadrupole field where Aq=0 is not limited thereto, and can be freely determined. The method for determining the orientation of the quadrupole field is not limited thereto.

In addition, the multipole that forms the quadrupole field is not limited to the octupole, and the strength and the rotation angle of the quadrupole field can be similarly freely controlled as long as the multipole has 2i poles (i is an integer of 4 or more).

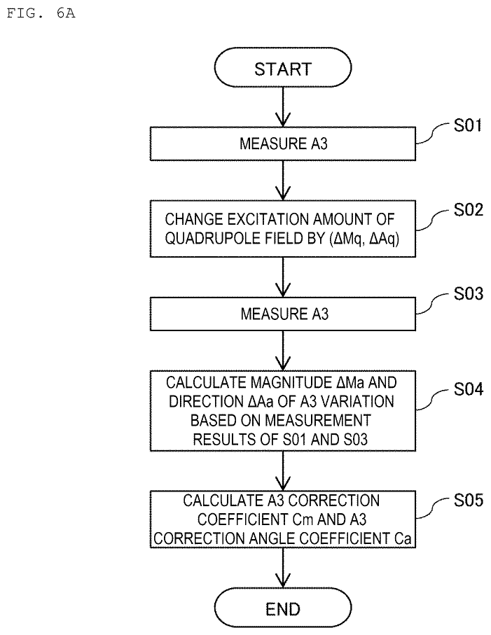

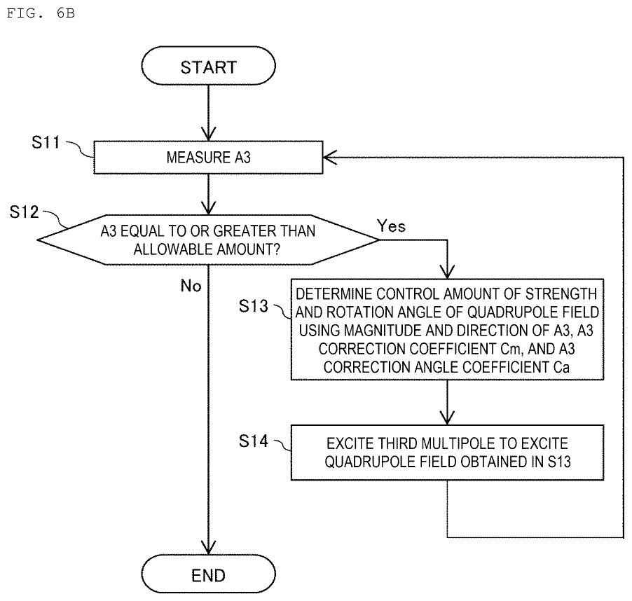

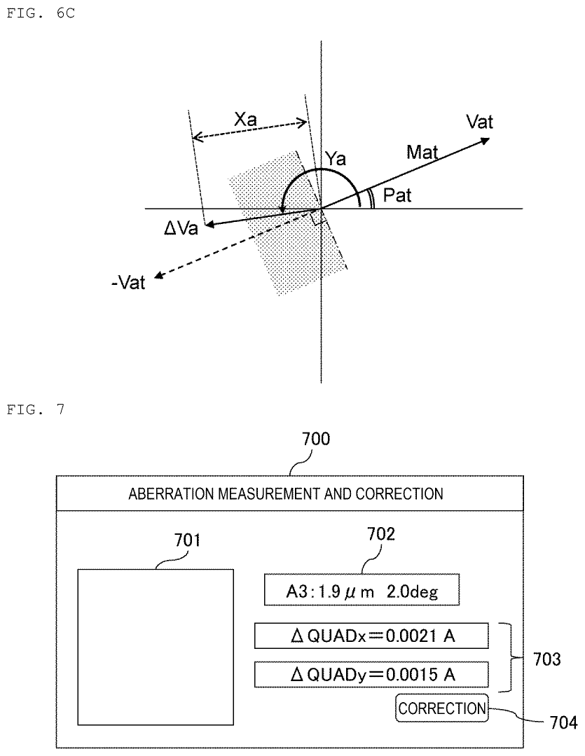

FIGS. 6A and 6B are flowcharts for controlling A3 executed by the controller 110. FIG. 6A is a flow for calculating an A3 correction coefficient Cm and an A3 correction angle coefficient Ca, which is executed prior to starting use of the charged particle beam device.

First, A3 is measured (S01). A3 measured in step S01 is defined as Va1. Here, Va1 is a vector quantity represented on a complex plane and includes two components of a magnitude and a direction. The direction of A3 is defined as an angle that A3 forms with four-fold spatial symmetry with respect to a reference direction perpendicular to the optical axis 111. The reference direction is freely determined for each optical system of the charged particle beam device or an aberration correction device. A3 is spatially four-fold symmetric, and is identical when rotated 90 degrees. Therefore, the direction Aa of A3 can be considered to have one period of 90 degrees, and four times a spatial direction (Pa=4×Aa) can be used as the direction of A3. As a method for measuring the aberration, a known method may be used. As one of methods, a measurement method using a projection pattern (Ronchigram) of an electron beam transmitted through a sample is known.

Subsequently, an excitation amount of the quadrupole field excited by the third multipole 207 is changed (S02), and A3 is measured again (S03). Assuming that a variation amount of the quadrupole field in step S02 is represented by (ΔMq,ΔAq), when the quadrupole field before the variation is represented by (Mq1,Aq1) and the quadrupole field after the variation is represented by (Mq2,Aq2), ΔMq has a magnitude represented by (Math 1) and ΔAq has a magnitude represented by (Math 2).

$$Δ Mq = \sqrt{{( Mq 1 )}^{2} + {( Mq 2 )}^{2} - 2 \times Mq 1 \times Mq 2 \times cos ( Aq 2 - Aq 1 )} \qquad [ Math . 1 ]$$

$$Δ Aq = \frac{180}{π} \times Arctan ( \frac{sin ( Aq 2 ) - sin ( Aq 1 )}{cos ( Aq 2 ) - cos ( Aq 1 )} ) \qquad [ Math . 2 ]$$

The variation amount may be expressed as (ΔMq,ΔPq) using a relationship of ΔPq=2×ΔAq.

It is assumed that A3 measured in step S03 is Va2. Va2 is also a vector quantity represented on the complex plane, and includes two components of the magnitude and the direction. In the following description, it is assumed that A3 decreases due to a change in the excitation amount of the quadrupole field in step S02.

Subsequently, the magnitude ΔMa and the direction ΔAa (or ΔPa) of the A3 variation due to the change in the excitation amount of the quadrupole field are calculated based on measurement results in steps S01 and S03 (S04). Here, the magnitude ΔMa is obtained by taking a difference between Va2 and Va1 measured in steps S01 and S03, as |Va2−Va1|. The direction ΔAa is an angle amount obtained by Math. 3.

$$Δ Aa = \frac{180}{π} \times Arctan ( \frac{Imag ( Va 2 - Va 1 )}{Real ( Va 2 - Va 1 )} ) \qquad [ Math . 3 ]$$

Imag(X) is an imaginary component of a complex vector X, and Real(X) is a real component of the complex vector X.

Subsequently, the A3 correction coefficient Cm and the A3 correction angle coefficient Ca are calculated (S05). The A3 correction coefficient is obtained as Cm=ΔMa/ΔMq, and the A3 correction angle coefficient is obtained as Ca=ΔAq−2×ΔAa+π/2. The A3 correction coefficient Cm and the A3 correction angle coefficient Ca calculated in step S05 are stored in a storage device included in the controller 110.

FIG. 6B is a flow showing a process for, for example, setting a parameter (here, the excitation amount of the third multipole) for controlling A3 to be equal to or less than an allowable amount, which is executed during maintenance of the aberration corrector 120. First, A3 is measured (S11). When A3 measured in step S11 is Vat, the magnitude of A3 is Mat and the direction is Pat (or Aat=Pat/4). Subsequently, the necessity of the control of A3 is determined. When the magnitude Mat of A3 measured in step S11 is equal to or less than the allowable value, the control is not necessary, and the process ends. On the other hand, when the magnitude of A3 exceeds the allowable value, the excitation amount of the third multipole is determined (S13). Thereafter, the predetermined quadrupole field obtained in step S13 is excited in the third multipole (S14), and in this state, it is confirmed that the magnitude of A3 is equal to or less than the allowable value, and the process ends.

Step S13 will be described. It is necessary to generate a quadrupole field that at least reduces the magnitude of the measured A3. FIG. 6C shows Vat indicating the measured A3 and the A3 variation ΔVa caused by controlling the quadrupole field. Hereinafter, the rotation angle of the quadrupole field, which is two-fold symmetric, and the orientation of A3, which is four-fold symmetric, are treated in a unified manner as both rotating once in 2π by using Pq and Pa, respectively.

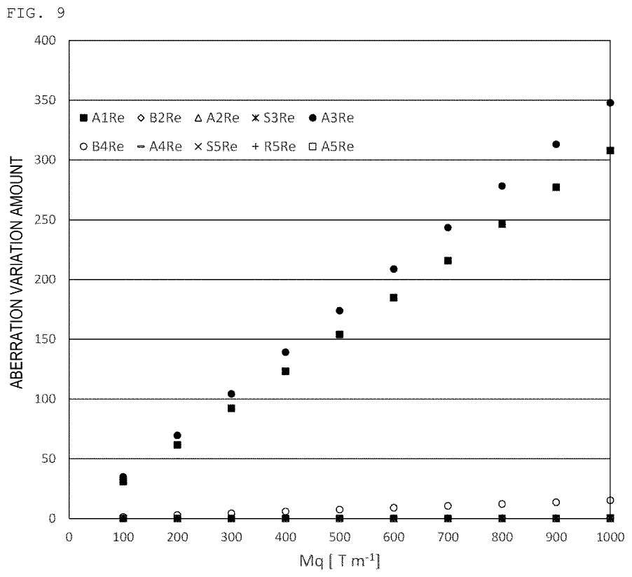

The quadrupole field is varied so as to act in a direction to cancel A3 (Vat) measured in step S11. At this time, the magnitude of the A3 variation is proportional to a change amount in the strength of the quadrupole field (see FIG. 8, 9 described later). Therefore, assuming that the control amount of the strength of the quadrupole field is ΔMqt and the magnitude of the A3 variation changed thereby is Xa, a relationship of ΔMa/ΔMq=Xa/ΔMqt is established. Therefore, the control amount ΔMqt=Xa×(ΔMq/ΔMa)=Xa/Cm can be calculated. Theoretically, when Xa=Mat, the magnitude of A3 is 0, and when Xa=2Mat, A3 is generated in an opposite direction with the same magnitude. Therefore, at least the control amount ΔMqt<2Mat×(ΔMq/ΔMa) is set.

Meanwhile, a relationship (ΔPq-ΔPa) between the direction in which the quadrupole field is changed (variation direction of the quadrupole field) and an accompanying orientation of the A3 variation (variation direction of A3) remains unchanged. That is, a relationship of ΔPqt−Ya=ΔPq−ΔPa is established, where ΔPqt (=2ΔAqt) is a direction in which the quadrupole field is changed, and Ya is the orientation of the A3 variation changed accordingly. When the orientation Ya of the A3 variation satisfies |Ya−(Pat+π)|<π/2, then at least a part of the vector Vat is cancelled out by ΔVa. Therefore, the quadrupole field variation in the orientation of ΔPqt may be generated such that |ΔPqt−ΔPq+ΔPa−Pat−π|<π/2 is satisfied. Here, an angle notation can be replaced using the relationship of Pq=2Aq and Pa=4Aa. That is, the quadrupole field variation in the orientation of ΔAqt may be generated so that |ΔAqt−2Aat−Ca|<π/4 is satisfied by using |ΔAqt−ΔAq+2ΔAa−2Aat−π/2|<π/4 and the A3 correction angle coefficient Ca=ΔAq−2×ΔAa+π/2. Further, when ΔAqt=ΔAq−2ΔAa+2Aat+π/2, A3 varies in a direction exactly opposite to A3 measured in step S11, so that A3 is most efficiently controlled.

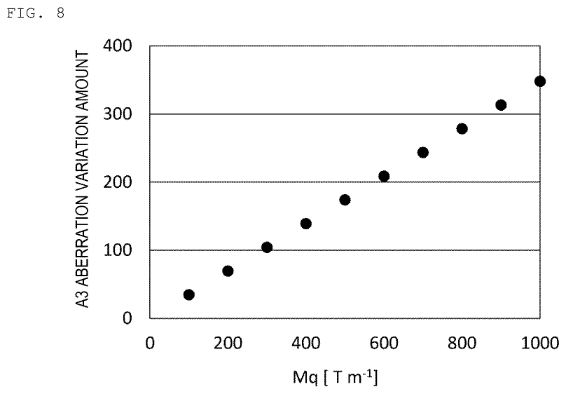

FIG. 7 shows an example of a GUI screen to be displayed on the display device included in the controller 110 in the flow of FIG. 6B. A GUI screen 700 includes the following display unit. An image display unit 701 displays an observation image or an observation pattern for obtaining A3 in step S11. In step S11, an aberration display unit 702 displays an aberration calculated based on the observation image or the observation pattern displayed on the image display unit 701. In the example of FIG. 7, the magnitude Mat of A3 and the rotation direction Aat of A3 are shown. In step S13, a control amount display unit 703 displays the determined control amounts of the strength and the rotation angle of the quadrupole field. The form of display is not limited, and in the example of FIG. 7, the control amount is displayed as a two-dimensional coordinate system (ΔQUADx,ΔQUADy). Here, the control amount is indicated by an excitation current (unit: ampere). The user may manually correct a value indicated in the control amount display unit 703. By pressing a correction button 704, the excitation of the third multipole 207 in step S14 is executed. When the value indicated in the control amount display unit 703 is corrected and the correction button 704 is pressed, the controller 110 excites the third multipole 207 with a control amount corresponding to the corrected value.

Effects of the present embodiment will be described with reference to FIGS. 8 and 9. FIG. 8 shows a change in the magnitude of A3 when the strength of the excited quadrupole field is changed. A change in the magnitude Ma of A3 when the strength Mq of the quadrupole field is changed under predetermined optical conditions is obtained by simulation. A horizontal axis represents the strength Mq of the quadrupole field (here, represented by the excitation amount), and a vertical axis represents a value obtained by normalizing the magnitude Ma of A3 obtained by the simulation with a resolution reference value (the value is referred to as an A3 aberration variation amount, which is a dimensionless number). As described above, the A3 aberration variation amount linearly changes with respect to the strength Mq of the quadrupole field. By using the characteristic, A3 generated as a parasitic aberration of the aberration corrector 120 can be controlled.

In FIG. 9, a behavior of parasitic aberration other than A3 is added to FIG. 8. In addition to A3 shown in FIG. 8, for nine types of parasitic aberrations, a change in the magnitude of the parasitic aberration when the strength Mq of the quadrupole field was changed under the same optical condition is obtained by simulation. Also in FIG. 9, a vertical axis indicates the magnitude of the parasitic aberration obtained by the simulation as an aberration variation amount normalized by the resolution reference value for each parasitic aberration. Although there are various absolute values of these parasitic aberrations, it is possible to compare influences on different parasitic aberrations by comparing the absolute values as the aberration variation amounts indicating influences on resolution. It can be seen from FIG. 9 that, by controlling the quadrupole field, A1 (two-fold symmetric first-order astigmatism) is also affected, although more gradually than A3, whereas the other eight types of parasitic aberration are hardly affected by the control of the quadrupole field.

As shown in FIG. 9, since the A1 aberration variation amount linearly changes with respect to the strength Mq of the quadrupole field, the variation of the aberration of A1 can be estimated based on the control amount of the quadrupole field. Therefore, it is possible to efficiently control the parasitic aberration of the aberration corrector 120 by calculating the variation amount of A1 according to the control of A3 and performing the control including the variation amount caused by the A3 control in the control of A1. Therefore, in the flow of FIG. 6A, A1 is measured in steps S01 and S03, and the variation amount in A1 according to the control amount of the quadrupole field is calculated and stored. In the flow of FIG. 6B, the variation amount of A1 is calculated based on the control amount of the quadrupole field determined in step S13 using the stored information.

Although the invention is specifically described based on the embodiment and the modification, the invention is not limited thereto, and various modifications can be made without departing from the gist of the invention. It is also effective to apply the embodiment and the modification in combination rather than alone.

### REFERENCE SIGNS LIST

100: mirror body
101: electron source
102, 103: focusing lens
104: aperture
105: pre-objective lens
106: sample
107: post-objective lens
108: projection lens
109: detector
110: controller
111: optical axis
120: aberration corrector
201: first multipole
202: second multipole
203: first electromagnetic lens
204: second electromagnetic lens
205: third electromagnetic lens
206: fourth electromagnetic lens
207: third multipole
211A, 211B, 212A, 212B, 213A, 213B, 221A, 221B, 222A, 222B,
501A, 501B, 501C, 501D, 511A, 511B, 511C, 511D: pole
401: fifth electromagnetic lens
402: sixth electromagnetic lens
500: quadrupole field
700: GUI screen
701: image display unit
702: aberration display unit
703: control amount display unit
704: correction button

1. An aberration corrector comprising:
first and second multipoles disposed along an optical axis and configured to excite a hexapole field;
first and second electromagnetic lenses disposed between the first multipole and the second multipole and constituting a transfer optical system; and
a third multipole disposed at a crossover of the transfer optical system and configured to excite a quadrupole field, wherein
at least one of a strength and a rotation angle of the quadrupole field excited by the third multipole is controlled to selectively control a four-fold symmetric third-order astigmatism.

2. The aberration corrector according to claim 1, wherein
a control amount of the strength and the rotation angle of the quadrupole field excited by the third multipole is calculated based on a magnitude and a direction of the four-fold symmetric third-order astigmatism that changes according to the strength and the rotation angle of the quadrupole field excited by the third multipole.

3. A charged particle beam device comprising:
a mirror body accommodating an electron optical system including an aberration corrector; and
a controller, wherein
the aberration corrector includes
first and second multipoles disposed along an optical axis and configured to excite a hexapole field,
first and second electromagnetic lenses disposed between the first multipole and the second multipole and constituting a transfer optical system, and
a third multipole disposed at a crossover of the transfer optical system and configured to excite a quadrupole field, and
the controller selectively controls a four-fold symmetric third-order astigmatism by controlling at least one of a strength and a rotation angle of the quadrupole field excited by the third multipole.

4. The charged particle beam device according to claim 3, wherein
the aberration corrector includes a third electromagnetic lens that causes an electron beam from the electron optical system to enter the first multipole as a collimated beam, and a fourth electromagnetic lens that focuses the electron beam from the second multipole and emits the focused electron beam to the electron optical system.

5. The charged particle beam device according to claim 3, wherein
the controller calculates the four-fold symmetric third-order astigmatism based on an observation image or an observation pattern, and calculates, based on information about a four-fold symmetric third-order astigmatism variation caused by a variation in the quadrupole field excited by the third multipole, a control amount of the quadrupole field excited by the third multipole for the four-fold symmetric third-order astigmatism to be equal to or less than an allowable amount.

6. The charged particle beam device according to claim 5, wherein
when a magnitude of the four-fold symmetric third-order astigmatism Vat calculated by the controller is Mat, and a magnitude of the four-fold symmetric third-order astigmatism variation corresponding to a magnitude ΔMq of a change amount of the quadrupole field excited by the third multipole is ΔMa, the controller sets a variation amount ΔMqt of the strength of the quadrupole field excited by the third multipole to satisfy ΔMqt<2Mat×(ΔMq/ΔMa).

7. The charged particle beam device according to claim 5, wherein
when an orientation of the four-fold symmetric third-order astigmatism Vat calculated by the controller is Aat and an orientation of the four-fold symmetric third-order astigmatism variation corresponding to a variation direction ΔAq of the quadrupole field excited by the third multipole is ΔAa, the controller sets a variation direction ΔAqt of the quadrupole field excited by the third multipole to satisfy |ΔAqt−ΔAq+2ΔAa−2Aat−π/2|π/4.

8. The charged particle beam device according to claim 7, wherein
the controller sets the variation direction ΔAqt of the quadrupole field excited by the third multipole to ΔAqt=ΔAq−2ΔAa+2Aat+π/2.

9. The charged particle beam device according to claim 5, wherein
the controller displays a GUI screen on a display device, and
the GUI screen includes an image display unit that displays the observation image or the observation pattern, and an aberration display unit that displays at least one of a magnitude and a rotation direction of the calculated four-fold symmetric third-order astigmatism.

10. The charged particle beam device according to claim 5, wherein
the controller calculates a variation amount of a two-fold symmetric first-order astigmatism according to the calculated control amount of the quadrupole field excited by the third multipole.

11. An aberration correction method to be performed in a charged particle beam device including a controller and a mirror body accommodating an electron optical system including an aberration corrector, wherein
the aberration corrector includes first and second multipoles disposed along an optical axis and configured to excite a hexapole field, first and second electromagnetic lenses disposed between the first multipole and the second multipole and constituting a transfer optical system, and a third multipole disposed at a crossover of the transfer optical system and configured to excite a quadrupole field, and
the controller selectively controls a four-fold symmetric third-order astigmatism by controlling at least one of a strength and a rotation angle of the quadrupole field excited by the third multipole.

12. The aberration correction method according to claim 11, wherein
the controller calculates the four-fold symmetric third-order astigmatism based on an observation image or an observation pattern, and calculates, based on information about a four-fold symmetric third-order astigmatism variation caused by a variation in the quadrupole field excited by the third multipole, a control amount of the quadrupole field excited by the third multipole for the four-fold symmetric third-order astigmatism to be equal to or less than an allowable amount.

13. The aberration correction method according to claim 12, wherein
when a magnitude of the four-fold symmetric third-order astigmatism Vat calculated by the controller is Mat, and a magnitude of the four-fold symmetric third-order astigmatism variation corresponding to a magnitude ΔMq of a change amount of the quadrupole field excited by the third multipole is ΔMa, the controller sets a control amount ΔMqt of the strength of the quadrupole field excited by the third multipole to satisfy ΔMqt<2Mat×(ΔMq/ΔMa).

14. The aberration correction method according to claim 12, wherein
when an orientation of the four-fold symmetric third-order astigmatism Vat calculated by the controller is Aat and an orientation of the four-fold symmetric third-order astigmatism variation corresponding to a variation direction ΔAq of the quadrupole field excited by the third multipole is ΔAa, the controller sets a variation direction ΔAqt of the quadrupole field excited by the third multipole to satisfy |ΔAqt−ΔAq+2ΔAa−2Aat−π/2|<π/4.

15. The aberration correction method according to claim 14, wherein
the controller sets the variation direction ΔAqt of the quadrupole field excited by the third multipole to ΔAqt=ΔAq−2ΔAa+2Aat+π/2.

16. The aberration correction method according to claim 12, wherein
the controller calculates a two-fold symmetric first-order astigmatism variation according to the calculated control amount of the quadrupole field excited by the third multipole.
